(19) United States
(12) Patent Application Publication
(10) Pub. No.: US 2021/0184039 A1
(43) Pub. Date: Jun. 17, 2021

(54) THIN FILM TRANSISTOR AND METHOD FOR MANUFACTURING THE SAME

(71) Applicant: SHENZHEN CHINA STAR OPTOELECTRONICS SEMICONDUCTOR DISPLAY TECHNOLOGY CO., LTD., Shenzhen, (CN)

(72) Inventor: Fangmei LIU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/618,369

(22) PCT Filed: Nov. 4, 2019
(86) PCT No.: PCT/CN2019/115430

§ 371 Date: Dec. 1, 2019

(30) Foreign Application Priority Data
Aug. 9, 2019 (CN) 201910732775.0

(51) Int. Cl. H01L 29/786; H01L 29/66

(52) U.S. Cl. CPC H01L 29/7869; H01L 29/66742; H01L 29/78618

(57) ABSTRACT

A thin film transistor and a method for manufacturing the same are disclosed. The thin film transistor includes a substrate, a gate, an insulation layer, a first active layer, a second active layer, a source, a drain, and a protection layer. The gate is disposed on the substrate. The insulation layer covers the gate. The first active layer is disposed on the insulation layer and above the gate. The second active layer is disposed on the first active layer, wherein a material of the second active layer is a metal oxide in which oxygen vacancies are filled with nitrogen. The source is disposed on the second active layer. The drain is disposed on the second active layer, wherein the source and the drain are above two opposite sides of the gate. The protection layer covers the first active layer, the second active layer, the source, and drain.

### FIELD OF INVENTION

The present disclosure relates to the technical field of metal oxide semiconductor devices and a method for manufacturing the same, and specifically to thin file transistors belonging to back channel etch (BCE) type metal oxide semiconductors and a method for manufacturing the same.

### BACKGROUND OF INVENTION

Thin film transistors (TFTs) belonging to back channel etch (BCE) type metal oxide semiconductors have advantages, such as a simple process, small parasitic capacitance and high aperture ratio. With “gate on array” (GOA) technology introduced into a display manufacturing process, requirements for uniformity and stability of electrical performance of the TFT devices are increasingly urgent.

Taking an example that metal oxide (such as indium gallium zinc oxide, IGZO) serves as an active layer, a conventional method for manufacturing the thin film transistors will bombard an IGZO target by argon (Ar) plasma during IGZO coating, and controls a concentration of oxygen vacancies in the IGZO by oxygen, and then manufactures a drain/source made of metal materials on the IGZO.

Taking an example that the source/drain is made of molybdenum-titanium alloy and copper (Mo—Ti/Cu), since oxygen in IGZO and titanium in the source/drain will combine with each other, to form a titanium oxide (TiO) layer at an interface between the IGZO and the source/drain, resulting in a large number of oxygen vacancies in the IGZO. Since an oxygen vacancy is generated, two free electrons are released, so that the active layer (i.e., IGZO) in a region around the titanium oxide has high electrically conductive, that causes the actual channel length to be shortened, so that the thin film transistors with a small channel design value easily generate an effect of drain induced barrier lowering (DIBL).

Therefore, the prior art has drawbacks and needs to be improved.

### SUMMARY OF INVENTION

The present disclosure is to provide a thin film transistor and a method for manufacturing the same to solve a problem of an effect of drain induced barrier lowering easily generated in the thin film transistor in the prior art.

In order to solve the above problem, an aspect of the present disclosure is to provide a thin film transistor, which includes a substrate; a gate disposed on the substrate; an insulation layer covering the gate; a first active layer disposed on the insulation layer and above the gate, wherein a material of the first active layer is a metal oxide in which oxygen vacancies are filled with oxygen; a second active layer disposed on the first active layer, wherein a material of the second active layer is a metal oxide in which oxygen vacancies are filled with nitrogen; a source disposed on the second active layer; a drain disposed on the second active layer, wherein the source and the drain are located above two opposite sides of the gate, and each of the source and the drain has a metal nitride layer abutting the second active layer; and a protection layer covering the first active layer, the second active layer, the source, and drain.

In an embodiment of the present disclosure, each of the source and the drain has a metal portion away from the second active layer.

In an embodiment of the present disclosure, a thickness range of the first active layer includes a first upper limit and a first lower limit, and a thickness range of the second active layer includes a second upper limit and a second lower limit, and the second upper limit is equal to the first lower limit.

In order to solve the above problem, another aspect of the present disclosure is to provide a thin film transistor, which includes a substrate; a gate disposed on the substrate; an insulation layer covering the gate; a first active layer disposed on the insulation layer and above the gate; a second active layer disposed on the first active layer, wherein a material of the second active layer is a metal oxide in which oxygen vacancies are filled with nitrogen; a source disposed on the second active layer; a drain disposed on the second active layer, wherein the source and the drain are located above two opposite sides of the gate; and a protection layer covering the first active layer, the second active layer, the source, and drain.

In an embodiment of the present disclosure, a material of the first active layer is a metal oxide in which oxygen vacancies are filled with oxygen.

In an embodiment of the present disclosure, each of the source and the drain has a metal nitride layer abutting the second active layer.

In an embodiment of the present disclosure, each of the source and the drain has a metal portion away from the second active layer.

In an embodiment of the present disclosure, a thickness range of the first active layer includes a first upper limit and a first lower limit, and a thickness range of the second active layer includes a second upper limit and a second lower limit, and the second upper limit is equal to the first lower limit.

Another aspect of the present disclosure is to provide a method for manufacturing a thin film transistor, which includes preparing a substrate; manufacturing a gate on the substrate; depositing an insulation layer covering the gate; depositing a metal oxide as a first active layer on the insulation layer; depositing another metal oxide as a second active layer on the first active layer and introducing argon and nitrogen during depositing the second active layer; manufacturing a source and a drain on the second active layer; and depositing a protection layer covering the first active layer, the second active layer, the source, and the drain.

In an embodiment of the present disclosure, argon and oxygen are introduced during depositing the first active layer.

In an embodiment of the present disclosure, each of the source and the drain has a metal nitride layer abutting the second active layer.

In an embodiment of the present disclosure, each of the source and the drain has a metal portion away from the second active layer.

In an embodiment of the present disclosure, a thickness range of the first active layer includes a first upper limit and a first lower limit, and a thickness range of the second active layer includes a second upper limit and a second lower limit, and the second upper limit is equal to the first lower limit.

Compared with the other technology (such as adopting a single-layered active layer), a double-layered active layer is adopted in a thin film transistor and a method for manufacturing the same provided by the present disclosure, wherein argon and nitrogen are introduced during depositing the second active layer. Since nitrogen can stay in the second active layer to fill oxygen vacancies more than oxygen, such that an effective channel of the present disclosure have a longer length, which can be used for suppressing the effect of drain induced barrier lowering, and effectively improve a case that the thin film transistor adopting the single-layered structure easily generates the effect of drain induced barrier lowering.

### BRIEF DESCRIPTION OF DRAWINGS

FIG. 1 is a schematic diagram illustrating a thin film transistor, according to an embodiment of the present disclosure;

FIG. 2 is a schematic diagram illustrating another thin film transistor compared with the above embodiment of the present disclosure.

### DETAILED DESCRIPTION OF PREFERRED EMBODIMENTS

Following a description of the various embodiments refers to additional drawings for illustrating specific embodiments of the present disclosure. Furthermore, directional terms mentioned in the present disclosure, such as upper, lower, top, bottom, front, rear, left, right, inner, outer, side, surrounding, central, horizontal, lateral, vertical, longitudinal, axial, radial, uppermost or lowermost, etc., which only refer to the direction of drawings. Therefore, the directional terms used as above are for the purpose of illustration and understanding of the present disclosure, and are not intended to limit the present disclosure.

A method for manufacturing a thin film transistor (TFT) according to an embodiment of the present disclosure may be used to manufacture a thin film transistor belonging to a back channel etch (BCE) type metal oxide semiconductor. For example, the metal oxide semiconductor may be indium gallium zinc oxide (IGZO), but is not limited thereto. The metal oxide semiconductor also may be selected from such as zinc oxide (ZnO), indium oxide (InO), gallium oxide (GaO), indium gallium oxide (IGO), indium zinc oxide (IZO), zinc tin oxide (ZTO), and indium zinc tin oxide (IZTO), or other materials. In the present embodiment, mainly take IGZO as an example, the following is an example of an implementation of the above thin film transistor, but it is not limited thereto.

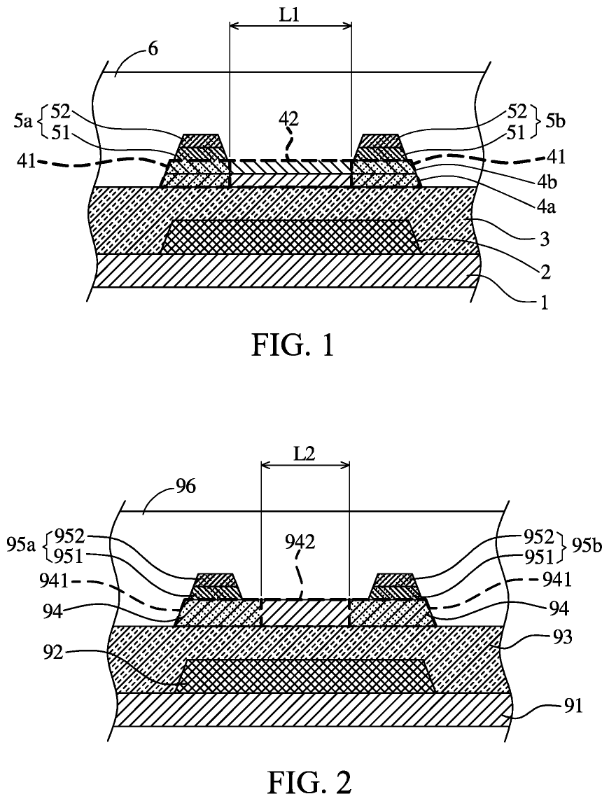

Please refer to FIG. 1, a thin film transistor according to an embodiment of the present disclosure may include a substrate 1, a gate 2, an insulation layer 3, a first active layer 4a, a second active layer 4b, a source 5a, a drain 5b, and a protection layer 6. The gate 2 may be disposed on the substrate 1. The insulation layer 3 may cover the gate 2. The first active layer 4a may be disposed on the insulation layer 3 and above the gate 2. The second active layer 4b may be disposed on the first active layer 4a, wherein a material of the second active layer 4b is a metal oxide in which oxygen vacancies are filled with nitrogen (N). The source 5a may be disposed on the second active layer 4b. The drain 5b may be disposed on the second active layer 4b, wherein the source 5a and the drain 5b are located above two opposite sides of the gate 2. The protection layer 6 may cover the first active layer 4a, the second active layer 4b, the source 5a, and the drain 5b, to protect the first active layer 4a, the second active layer 4b, the source 5a, and the drain 5b from the external environment. Specifically, the protection layer 6 also may cover the insulation layer 3, such as depositing the protection layer 6 on the insulation layer 3.

For example, as shown in FIG. 1, a material of the substrate may be glass, flexible substrate material, or the like. A material of the gate 2 may be metal material, such as molybdenum-titanium alloy and copper (Mo—Ti/Cu) mixture or molybdenum-copper (Mo/Cu) mixture, etc. A material of the insulation layer 3 may be silicon oxide (SiOx) or silicon nitride (SiNx), where x is a reasonable number.

As shown in FIG. 1, a material of the first active layer 4a is a metal oxide in which oxygen vacancies are filled with oxygen (O), such as IGZO in which oxygen vacancies are filled with oxygen. A material of the second active layer 4b is a metal oxide in which oxygen vacancies are filled with nitrogen (N), such as IGZO in which oxygen vacancies are filled with nitrogen. Therefore, a characteristic that the electronegativity of nitrogen is weaker than that of oxygen can be effectively used to fill the oxygen vacancies of metal oxide by utilizing nitrogen ions, so as to reduce a conductive area and increase an effective length of a channel.

In the present embodiment, a thickness range of the first active layer 4a includes a first upper limit (such as 400 Å) and a first lower limit (such as 200 Å), and a thickness range of the second active layer 4b includes a second upper limit (such as 200 Å) and a second lower limit (such as 50 Å), and the second upper limit is equal to the first lower limit.

As shown in FIG. 1, a material of each of the source 5a and the drain 5b may be selected from copper (Cu), aluminum (Al), nickel (Ni), magnesium (Mg), chromium (Cr), titanium (Ti), molybdenum (Mo), tungsten (W), or alloys thereof. Each of the source 5a and the drain 5b has a metal nitride layer 51, such as titanium nitride, wherein the metal nitride layer 51 abuts the second active layer 4b. Each of the source 5a and the drain 5b has a metal portion 52, such as molybdenum-titanium alloy and copper (Mo—Ti/Cu) mixture, wherein the metal portion 52 is away from the second active layer 4b to prevent from undercuts.

Therefore, a double-layered active layer, such as IGZO, is adopted in the thin film transistor provided by the present disclosure. The source, the drain both together with the conductive region located on a surface of the second active layer only form a relatively thin layer of metal nitride, and the conductive region becomes shorter, such that an effective channel length of a channel region between the two conductive regions becomes longer. The following describes an example of a method for manufacturing the above thin film transistor, but is not limited thereto.

Please refer to FIG. 1 again, a method for manufacturing a thin film transistor according to the present disclosure may include the following steps: preparing a substrate 1; manufacturing a gate 2 on the substrate 1; depositing an insulation layer (GI) 3 covering the gate 2; depositing a metal oxide as a first active layer 4a on the insulation layer 3; depositing another metal oxide as a second active layer 4b on the first active layer 4a and introducing argon and nitrogen during depositing the second active layer 4b; manufacturing a source 5a and a drain 5b on the second active layer 4b; and depositing a protection layer 6, which can cover the first active layer 4a, the second active layer 4b, the source 5a, and the drain 5b. Specifically, the protection layer 6 also may cover the insulation layer 3.

For example, as shown in FIG. 1, firstly, the substrate 1 is prepared, such as cleaning and pre-baking the substrate 1 (such as a glass substrate) that can be used to fabricate a thin film transistor for subsequent steps.

Then, the gate 2 is manufactured on the substrate 1, depositing the gate 2 on the substrate 1 by utilizing physical vapor deposition (PVD). A material of the gate 2 may be molybdenum-titanium alloy and copper (Mo—Ti/Cu) mixture. A thickness of the gate 2 may between 3000 and 8000 angstrom (Å), and a patterning technology may be used to define a pattern.

Then, the insulation layer 3 is deposited, such as depositing a thin film layer of silicon oxide (SiOx) as the insulation layer 3 on the gate 2 by utilizing plasma enhanced chemical vapor deposition (PECVD), but is not limited thereto. The insulation layer 3 may be manufactured by depositing a thin film layer of silicon nitride (SiNx) and a thickness of the insulation layer 3 may be between 1000 and 5000 Å.

Then, a metal oxide is deposited as the first active layer 4a on the insulation layer 3, such as depositing a layer of IGZO as the first active layer 4a on the insulation layer 3 by utilizing PVD and introducing mixing gas including argon and oxygen (Ar/O2) during the depositing process, wherein the mixing ratio can be adjusted according to the actual application. In addition, a depositing thickness of the first active layer 4a may be between 200 and 400 Å.

Then, another metal oxide is deposited as the second active layer 4b on the first active layer 4a, such as depositing another layer of IGZO as the second active layer 4b by utilizing PVD and introducing mixing gas including argon and nitrogen (Ar/N2) during the depositing process, wherein the mixing ratio can be adjusted according to the actual application. In addition, a depositing thickness of the second active layer 4b may be between 50 and 200 Å, and a pattern may be defined by adopting such as yellow lighting and etching technology.

Then, the source 5a and the drain 5b are manufactured on the second active layer 4b, such as depositing the source 5a and the drain 5b on the second active layer 4b by utilizing PVD, wherein a material that is used to deposit the source 5a and the drain 5b may be such as Mo—Ti/Cu. In addition, thicknesses of the source 5a and the drain 5b may be between 3300 and 8000 Å, and a pattern may be defined by adopting such as yellow lighting and etching technology.

Then, the protection layer 6 is deposited, such as depositing at least one thin film layer of SiOx, SiNx, or SiOx/SiNx as the protection layer 6 by utilizing PECVD, wherein a thickness of the protection layer 6 may be between 1000 and 5000 Å.

It should be noted that, as shown in FIG. 1, the double-layered structure is used in the active layer according to the above embodiment of the present disclosure. When the first active layer 4a is deposited, the carrier gas is mixed with argon and oxygen (Ar/O2), and when the second active layer 4b is deposited, the carrier gas is mixed with argon and nitrogen (Ar/N2). Since nitrogen can fill oxygen vacancies like oxygen, the electronegativity of nitrogen is weaker than that of oxygen, and then nitrogen is used instead of oxygen, so that a number of ions chemically reacting with the metal elements of the source 5a and the drain 5b is smaller. For example, a small amount of nitrogen ions reacts with the titanium in the source 5a and the drain 5b, and does not react as strongly as that titanium reacts with a large amount of oxygen ions.

As shown in FIG. 1, the source 5a and the drain 5b of the above embodiments of the present disclosure only obtain a small amount of nitrogen around a plurality of conductive regions 41 of the second active layer 4b to form a relatively thin metal nitride (such as TiN), such that more nitrogen will remain in the second active layer 4b to fill the oxygen vacancies, and the conductive regions 41 become shorter, so that a length L1 of an effective channel of a channel region 42 between the conductive regions 41 becomes longer.

In comparison, as shown in FIG. 2, another thin film transistor adopting a single structure of active layer includes a substrate 91, a gate 92, an insulation layer 93, an active layer 94, a source 95a, a drain 95b, and a protection layer 96. Since the oxygen in the active layer (e.g., IGZO) 94 and the source 95a/drain 95b (e.g., Mo—Ti/Cu) are easily bonded to each other, such that a titanium oxide (TiO) layer 951 and a metal portion 952 are formed by contacting the source 95a/drain 95b with the IGZO. Higher oxygen vacancies are formed in the active layer 94, so that the conductivity of the two conductive regions 941 around the titanium oxide layer 951 becomes higher, resulting in a length L2 of an effective channel of a channel region 942 between the two conductive regions 941 is shortened. Thus, a thin film transistor having a small channel design value is liable to cause an effect of drain induced barrier lowering.

Therefore, compared with the other technology (such as adopting a single-layered active layer), a double-layered active layer is adopted in a thin film transistor and a method for manufacturing the same provided by the present disclosure, wherein argon and nitrogen are introduced during depositing the second active layer. Since nitrogen can stay in the second active layer to fill oxygen vacancies more than oxygen, such that an effective channel of the present disclosure have a longer length (as shown in FIGS. 1 and 2, L1 in FIG. 1 being longer than L2 in FIG. 2), which can be used for suppressing the effect of drain induced barrier lowering, and effectively improve a case that the thin film transistor adopting the single-layered structure easily generates the effect of drain induced barrier lowering.

In summary, although the present disclosure has been disclosed in the above preferred embodiments, the above preferred embodiments are not intended to limit the present disclosure. In addition, various modifications and changes may be made by those skilled in the art without departing from the spirit and scope of this application. Therefore, the scope of protection of this application is subject to the scope defined by the claims.

What is claimed is:

1. A thin film transistor, comprising:
a substrate;
a gate disposed on the substrate;
an insulation layer covering the gate;
a first active layer disposed on the insulation layer and above the gate, wherein a material of the first active layer is a metal oxide in which oxygen vacancies are filled with oxygen;
a second active layer disposed on the first active layer, wherein a material of the second active layer is a metal oxide in which oxygen vacancies are filled with nitrogen;
a source disposed on the second active layer;
a drain disposed on the second active layer, wherein the source and the drain are located above two opposite sides of the gate, and each of the source and the drain has a metal nitride layer abutting the second active layer; and
a protection layer covering the first active layer, the second active layer, the source, and the drain.

2. The thin film transistor as claimed in claim 1, wherein each of the source and the drain has a metal portion away from the second active layer.

3. The thin film transistor as claimed in claim 1, wherein a thickness range of the first active layer includes a first upper limit and a first lower limit, and a thickness range of the second active layer includes a second upper limit and a second lower limit, and the second upper limit is equal to the first lower limit.

4. A thin film transistor, comprising:
a substrate;
a gate disposed on the substrate;
an insulation layer covering the gate;
a first active layer disposed on the insulation layer and above the gate;
a second active layer disposed on the first active layer, wherein a material of the second active layer is a metal oxide in which oxygen vacancies are filled with nitrogen;
a source disposed on the second active layer;
a drain disposed on the second active layer, wherein the source and the drain are located above two opposite sides of the gate; and
a protection layer covering the first active layer, the second active layer, the source, and drain.

5. The thin film transistor as claimed in claim 4, wherein a material of the first active layer is a metal oxide in which oxygen vacancies are filled with oxygen.

6. The thin film transistor as claimed in claim 4, wherein each of the source and the drain has a metal nitride layer abutting the second active layer.

7. The thin film transistor as claimed in claim 6, wherein each of the source and the drain has a metal portion away from the second active layer.

8. The thin film transistor as claimed in claim 4, wherein a thickness range of the first active layer includes a first upper limit and a first lower limit, and a thickness range of the second active layer includes a second upper limit and a second lower limit, and the second upper limit is equal to the first lower limit.

9. A method for manufacturing a thin film transistor, comprising:
preparing a substrate;
manufacturing a gate on the substrate;
depositing an insulation layer covering the gate;
depositing a metal oxide as a first active layer on the insulation layer;
depositing another metal oxide as a second active layer on the first active layer and introducing argon and nitrogen during depositing the second active layer;
manufacturing a source and a drain on the second active layer; and
depositing a protection layer covering the first active layer, the second active layer, the source, and the drain.

10. The method for manufacturing the thin film transistor as claimed in claim 9, wherein argon and oxygen are introduced during depositing the first active layer.

11. The method for manufacturing the thin film transistor as claimed in claim 9, wherein each of the source and the drain has a metal nitride layer abutting the second active layer.

12. The method for manufacturing the thin film transistor as claimed in claim 11, wherein each of the source and the drain has a metal portion away from the second active layer.

13. The method for manufacturing the thin film transistor as claimed in claim 9, wherein a thickness range of the first active layer includes a first upper limit and a first lower limit, and a thickness range of the second active layer includes a second upper limit and a second lower limit, and the second upper limit is equal to the first lower limit.
